(19) United States
(12) Patent Application Publication
(10) Pub. No.: US 2025/0257451 A1
(43) Pub. Date: Aug. 14, 2025

(54) HIGH DENSITY AMORPHOUS CARBON FILM WITH REDUCED HYDROGEN CONTENT

(71) Applicant: Applied Materials, Inc., Santa Clara, CA (US)

(72) Inventors: Ruiyun HUANG, Santa Clara, CA (US); Jun FENG, Santa Clara, CA (US); Yuxing ZHANG, Santa Clara, CA (US); Bryan LIAO, Sunnyvale, CA (US); Abhijit KANGUDE, Fremont, CA (US); Amit Kumar BANSAL, Milpitas, CA (US); Xinhai HAN, Santa Clara, CA (US); Karthik JANAKIRAMAN, San Jose, CA (US)

(21) Appl. No.: 19/051,679

(22) Filed: Feb. 12, 2025

Related U.S. Application Data
(60) Provisional application No. 63/552,463, filed on Feb. 12, 2024.

(51) Int. Cl. C23C 16/26; C23C 16/04; C23C 16/505

(52) U.S. Cl. CPC C23C 16/26; C23C 16/042; C23C 16/505

(57) ABSTRACT

Embodiments described herein generally relate to the fabrication of integrated circuits. More particularly, the implementations described herein provide techniques for deposition of amorphous carbon films on a substrate with improved etch selectivity. In certain embodiments, a method of forming an amorphous carbon film with film density close to the theoretical density of pure sp² graphite and reduced hydrogen content is provided.

### CROSS-REFERENCE TO RELATED APPLICATIONS

This application claims the benefit of U.S. Provisional Patent Application Ser. No. 63/552,463, filed Feb. 12, 2024, which is incorporated by reference herein in its entirety.

### BACKGROUND

### Field

Embodiments of the present disclosure generally relate to the fabrication of integrated circuits. More particularly, the embodiments described herein provide techniques for deposition of high density amorphous carbon films on a substrate.

### Description of the Related Art

Integrated circuits have evolved into complex devices that can include millions of transistors, capacitors and resistors on a single chip. The evolution of chip designs continually involves faster circuitry and greater circuit density. The demands for faster circuits with greater circuit densities impose corresponding demands on the materials used to fabricate such integrated circuits. In particular, as the dimensions of integrated circuit components are reduced to the sub-micron scale, low resistivity conductive materials as well as low dielectric constant insulating materials are used to obtain suitable electrical performance from such components.

The demands for greater integrated circuit densities also impose demands on the process sequences used in the manufacture of integrated circuit components. For example, in process sequences that use conventional photolithographic techniques, a layer of energy sensitive resist is formed over a stack of material layers deposited on a substrate. The energy sensitive resist layer is exposed to an image of a pattern to form a photoresist mask. Thereafter, the mask pattern is transferred to one or more of the material layers of the stack using an etch process. The etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer.

As the pattern dimensions are reduced, the thickness of the energy sensitive resist is correspondingly reduced in order to control pattern resolution. Such thin resist layers can be insufficient to mask the underlying material layer during the pattern transfer process from the etchant. An intermediate layer (e.g., silicon oxynitride, silicon carbine or carbon film), called a hardmask, may therefore be used between the energy sensitive photoresist and the underlying material layer to facilitate pattern transfer because of the hardmask's greater resistance to the etchant. During etching, the hardmask provides selective resistance to the etchants used to form features in the underlying material layers of the film stack according to the pattern created in the energy-sensitive resist. A hardmask without sufficient etch resistance may prematurely wear away during the course of etching high aspect ratios thereby resulting in inaccurate and poor pattern transfer.

Furthermore, poor selectivity between the hardmask and adjacent or underlying material layers may necessitate a thicker hardmask. Hardmasks with increased thickness may not be suitable for pattern transfer due to decreased transparency, and pattern bending or collapse at higher aspect ratios. As feature sizes decrease and aspect ratios increase in semiconductor device applications, hardmasks with increased etch selectivity are needed. As critical dimensions (CD) decrease, current hardmask materials lack the targeted etch selectivity relative to underlying materials and are often difficult to deposit.

Hardmask materials having both high etch selectivity and high deposition rates are desirable. Therefore, there is a need in the art for an improved hardmask and methods for depositing the improved hardmask on the substrate.

### SUMMARY

Embodiments of the present disclosure generally relate to the fabrication of integrated circuit. More particularly, in some embodiments, the present disclosure provides techniques for forming high density amorphous carbon films on a substrate for use as a hardmask. In one embodiment, a method for processing a substrate is provided. The method includes flowing a processing gas into a processing region of a process chamber having a substrate positioned on a substrate support and a material layer disposed on the substrate. The method also includes generating a deposition plasma from the processing gas by applying a RF power to the processing region to form the amorphous carbon film on the material layer. The RF power applied is in a range between about 1000 Wand about 7000 W. The substrate is maintained at a temperature between about 200 degrees Celsius and about 900 degrees Celsius when forming the amorphous carbon film. The method further includes patterning the amorphous carbon film in a pattern, and etching the pattern into the material layer.

In another embodiment, a method of processing a substrate is provided. The method includes positioning a substrate having a material layer disposed thereon on a substrate support in a processing region of a process chamber. The method also includes generating a deposition plasma of the processing gas by applying a RF power to the processing region to form the amorphous carbon film on the material layer. The RF power delivered for forming the amorphous carbon film has a range between about 1000 W and about 7000 W. The amorphous carbon film formed has a density greater than about 1.9 g/cc.

In yet another embodiment, a film for use in processing a substrate is provided. The film includes an amorphous carbon film formed by a plasma deposition process using a RF power between about 1000 W and about 7000 W, with the amorphous carbon film serving as a hardmask on the substrate in an etch process. In some embodiments, the amorphous carbon film has a density greater than about 1.9 g/cc and a hydrogen content of less than about 10%.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a process chamber, according to certain embodiments;

FIG. 2A is a schematic cross-sectional view of the process chamber of FIG. 1 configured with a RF return assembly, according to certain embodiments;

FIG. 2B is a schematic cross-sectional view of the RF return assembly in FIG. 2A, according to certain embodiments:

FIG. 3 depicts a process flow diagram of a method for forming an amorphous carbon hardmask, according to certain embodiments;

FIGS. 4A-4G depict a schematic cross-sectional view of a substrate structure illustrating a hardmask formation sequence, according to method depicted in FIG. 3; and

FIG. 5 depicts a process flow diagram of a method for forming an amorphous carbon film, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods for formation of an amorphous carbon hardmask with high density close to that of pure sp² graphite on a substrate are described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

The physical constraints in scaling down of integrated circuits have resulted in extension of integrated circuits orthogonal to the planar wafer surface, i.e., high aspect ratio (HAR), three-dimensional utilization of device space. Fabrication of memory and logic devices therefore may often involve etching features of a substrate, which may include multiple layers of materials. “Features” as used herein may describe negative features such as contact holes, openings, recesses, trenches, or vias. In one example, such as in 3D NAND applications, vertical features (e.g., channel openings) are created in semiconductor devices using a dry etch process with plasma reactive gases. As device stacks become thicker and aspect ratios of features increase to increase memory density and reduce per unit cost, it becomes increasingly challenging to etch such high aspect ratio features. The nanofabrication strategies to accommodate dynamic etch selectivity and increasingly stringent fabrication tolerances have resulted in a library of hardmask (HM) materials, such as carbon films doped with silicon, titanium, tungsten or boron; as well as dielectric silicon oxide-nitride (ON/OP) films. Used in combination, these materials offer advantages in etch selectivity and patterning down to the 1× node. Innovation in amorphous carbon hardmask materials is desirable for achieving high aspect ratio benchmarks in next generation device structures. In contrast to metal and dielectric solutions, amorphous carbon is ashable, providing high selectivity with respect to underlying ON/OP films.

When etching high aspect ratio features using a dry etch process, both the hardmask and underlying material layers are exposed to the gaseous chemical etchant, which preferentially etches away the underlying material layers. A hardmask with high etch selectivity is therefore important for successfully transferring patterns to the underlying material layers. For an amorphous carbon hardmask, film properties that influence etch selectivity include the density and hydrogen content of the film, among others. In conventional amorphous carbon hardmask, the hardmask may have a density of about 1.82 g/cc and hydrogen content greater than about 11%, such as between about 15% and about 30%.

However, current integrated hardware and processes for amorphous carbon hard masks demonstrate challenges regarding improvements in etch selectivity. Various strategies have been employed for modifying process regimes and parameters for improving etch selectivity of amorphous carbon hard mask. However, under current PECVD process regimes are limited, thereby making achieving the necessary improvements in etch selectivity challenging and with limited success. For example, due to the limitations of conventional process regimes, modifications often result in amorphous hardmasks with similar etch selectivity, low deposition rates, or altered surface morphology (e.g., increased surface roughness) that can degrade patterning performance and quality.

For an amorphous carbon films, film properties that can affect etch selectivity include but not limited to hydrogen content, film density, sp³ carbon bonding, and/or sp² carbon bonding. A higher sp²/sp² ratio in the amorphous film results in increased film density and hardness, thereby offering a higher etching resistance. Aspects of the present disclosure provides techniques and process regimes for forming amorphous carbon hardmasks with improved etch selectivity by increasing the density of the hardmask and reducing the hydrogen content thereof.

In one aspect of the present disclosure, etch selectivity of the amorphous carbon hardmask is improved by increasing the density of the hardmask to about 2.12 g/cc, close to the theoretical density of sp² graphite (2.26 g/cc). The density of the amorphous carbon hardmask may correlate with other properties of the hardmask, such as hardness, refractive index, extinction coefficient, and Young's modulus. Not to be bound by theory, but it was observed that increasing the ion bombardment energy (eV) of carbon ions from precursors in the processing gases during PECVD can improve carbon bonding and reduce hydrogen incorporation, thereby increasing a density of the amorphous carbon films being deposited on the substrate.

When the hydrocarbon precursors are coupled with high plasma power, an increased plasma density may be produced that may facilitate modifying the deposited film structure. For example, by applying a high bias power to generate a bias plasma (e.g., deposition plasma) with high plasma power, carbon ion bombardment with increased ion bombardment energy may be afforded during deposition. In such high-power scenarios, ion bombardment coupled with the increased ion bombardment energy during formation may improve the deposited film structure. For example, high ion energy and bombardment may slow the growth rate of carbon crystals in the carbon film and increase hydrogen removal, among other effects.

As discussed above, the ion bombardment energy during processing can be controlled by the plasma power utilized during deposition. In some embodiments, the plasma power is delivered as a bias power from a RF power source electrically connected to the substrate support of the process chamber. In one embodiment, high plasma power is provided by delivering a high bias power from the RF power source, such as by delivering a high RF power (>4000 Watts) to the substrate support in electrical contact with the substrate. In certain embodiments, to maintain the efficiency and stability of the high RF power delivered to the substrate support during processing, the high RF power may be delivered to the substrate support via a bottom RF feed. In another embodiment, the PECVD process chamber may also be implemented with a simplified and shorter RF return path design that eliminates parasitic plasma to maximize the impact of the increased ion bombardment energy afforded during processing. Furthermore, the applied high RF power may also assist in increasing a density of the plasma despite the low pressure of the deposition process utilized for achieving high ion energy and stabilizing the plasma during deposition.

In another aspect of the present disclosure, etch selectivity of the amorphous carbon hardmask is also improved by decreasing the hydrogen content of the amorphous carbon hardmask (e.g., from about 15-30% hydrogen content to less than about 8% hydrogen content). In one embodiment, the hydrogen content of the amorphous carbon hardmask formed is reduced by increasing the substrate temperature during deposition of the carbon film. Increases in substrate temperature during processing may in turn cause an increase in the amount of sp² carbon bonding in the carbon film being formed resulting in crystallization, growth of carbon crystals, and generally the amorphous carbon in the film becoming more graphitic/transitioning to nanocrystalline graphite. Such alterations concerning the transitioning of the carbon film to being more graphitic is usually not acceptable as they can result in changes in the surface roughness of the patterned carbon hardmask as well as mechanical properties thereof, such as reductions in the modulus and hardness. However, as mentioned above, it was observed that the increased ion bombardment energy provided to improve the deposited amorphous carbon film structure also counters and suppresses the crystallization and growth of the amorphous carbon in the as deposited film. By increasing the ion energy of the carbon ions for sub-plantation during deposition, the excess energy promotes thermal relaxation of the grown carbons, leading to the formation of sp² carbons. In some embodiments, the resulting amorphous carbon hardmask is formed with a surface roughness (Ra) of less than 1 nm. High carbon ion energy during deposition therefore also assists in enabling increasing substrate temperature during processing that may otherwise unacceptably cause the amorphous carbon in the film to grow, crystalize, and/or generally at least start transitioning to becoming more graphitic.

In some embodiments, the amorphous carbon hardmask is deposited via plasma enhanced chemical vapor deposition onto a substrate. In some embodiments, the hydrocarbon precursor is C₂H₂, with plasma profile and uniformity sustained by argon, helium, nitrogen or other suitable dilution gases. The scope of present disclosure may also encompass use of hydrocarbon precursors such as C₂H₂, C₃H₆, C₆H₁₂, and C₃H₈, among others. The resulting amorphous carbon hardmask provided by the present disclosure has shown an improvement in etch selectivity of at least about 30% as compared to conventional pure carbon hardmasks.

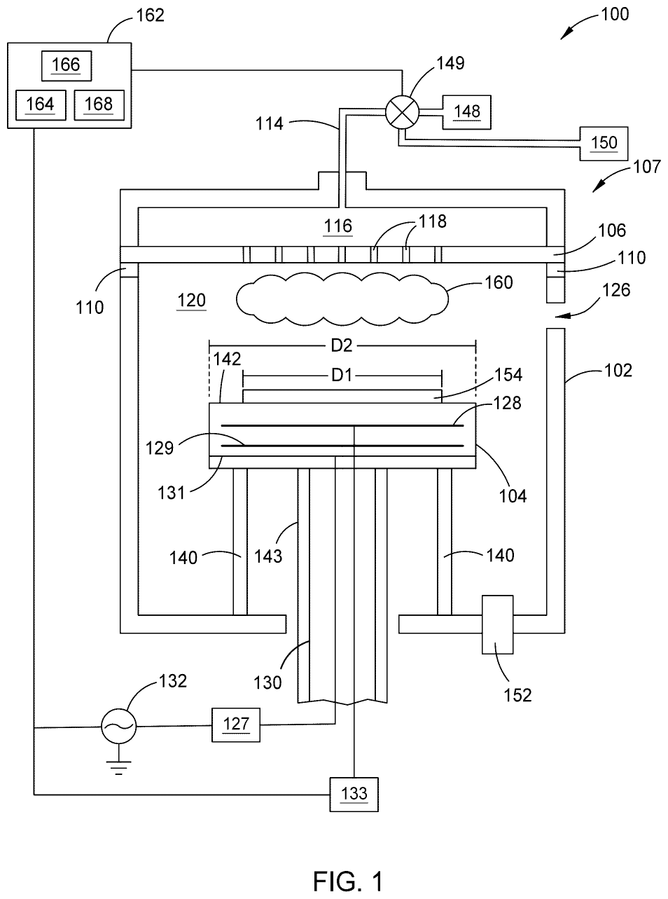

FIG. 1 is a schematic cross-sectional view of a process chamber 100 according to one example described herein. The process chamber 100 may be a plasma enhanced CVD (PECVD) chamber or other plasma enhanced process chamber. An exemplary process chamber which may benefit from the examples described herein is the PRODUCER® series of PECVD enabled chambers, available from Applied Materials, Inc., Santa Clara, Calif. It is contemplated that other similarly equipped process chambers from other manufacturers may also benefit from the examples described herein.

The process chamber 100 includes a chamber body 102, a substrate support 104 disposed inside the chamber body 102, and a lid assembly 107 coupled to the chamber body 102 and enclosing the substrate support 104 in a processing region 120. The lid assembly 107 includes a faceplate 106 comprising a gas distributor, such as a showerhead. Substrate 154 may be provided to the processing region 120 through an opening 126 formed in the chamber body 102. Faceplate 106 may at least partially define the processing region 120 from above, which may at least partially cooperate with the substrate support 104 in a raised position to generally define the processing region 120.

An isolator 110, which may be a dielectric material such as a ceramic or metal oxide, for example aluminum oxide and/or aluminum nitride, separates the faceplate 106 from the chamber body 102. The faceplate 106 includes openings 118 for admitting processing gases or cleaning gases into the processing region 120. Process gases may be supplied from a gas source 148, through a mass flow controller 149 into the process chamber 100 via a conduit 114. The gases may enter a gas mixing region 116 prior to flowing through the openings 118. In some embodiments, radicals for cleaning the processing region 120 may be provided by a remote plasma source 150. An exhaust 152 is formed in the chamber body 102 at a location below the substrate support 104. The exhaust 152 may be connected to a vacuum pump (not shown) to remove unreacted species and by-products from the process chamber 100.

The substrate support 104 includes a surface 142 for supporting the substrate 154. The substrate 154 has a dimension D1 (e.g., a diameter), and the substrate support 104 has a dimension D2 (e.g., a diameter), that may be greater than the dimension D1. The substrate support 104 may be formed from a ceramic material, for example a metal oxide or nitride or oxide/nitride mixture such as aluminum, aluminum oxide, aluminum nitride, or an aluminum oxide/nitride mixture. The substrate support 104 is supported by a shaft 143. The substrate support 104 may be grounded. A heating element 128 and a bias electrode 129 may be embedded in the substrate support 104. In some embodiments, the bias electrode 129 may also be a chucking electrode. The heating element 128 may be a plate, a perforated plate, a mesh, a wire screen, or any other distributed arrangement. The heating element 128 can be connected to a heating power source 133 and can heat the substrate 154 to an elevated temperature, such as from about 200 degrees Celsius to about 900 degrees Celsius.

In some embodiments, in order to minimize heat loss when heating the substrate 154 during processing, the substrate support 104 may further comprise a thermal isolation layer 131 disposed between the heating element 128 and a ground plate (not shown) to minimize heat loss during processing. Not to be bound by theory, but it is believed that by heating the substrate 154 to a high temperature during a plasma enhanced deposition process, the properties of the deposited amorphous carbon film can be adjusted. For example, performing a plasma deposition process at a temperature greater than about 650 degrees Celsius can advantageously reduce the hydrogen content of the as deposited amorphous carbon film formed.

In some embodiments, the substrate support 104 may also include a single electrically conductive rod (referred to as an “RF rod”) 130 disposed within at least a portion of the shaft 143 that is coupled to the substrate support 104. In some embodiments, the RF rod 130 extending through the shaft 143 couples the bias electrode 129 to an RF power source 132 through a match 127. In some embodiments, the RF power source 132 provides an RF current to the bias electrode 129 to deliver a RF bias power to the substrate support 104 and the substrate disposed thereon. The RF bias power from the RF power source 132 acts to energize (or “excite”) the processing gases in the processing region 120 into a bias plasma 160 to, for example, form an amorphous carbon film on a surface of the substrate 154 in the processing region 120. When exposed to plasma 160, constituents from the processing gases, including ions, neutrons, protons, and radicals are created when the processing gases may be disassociated by the application of RF generator or DC power source.

In some embodiments, the RF power source 132 may be a high frequency RF power source with a frequency between about 1 MHz and about 60 MHz for example, and in a particular embodiment, is in the 13.56 MHz band. In other embodiments, the RF power source 132 may be a dual-frequency RF power source, providing low and high frequency, such as a low frequency of 250 kHz, 2 MHz, or 400 kHz frequency power in combination with a 13.56 MHz frequency power. During a deposition process, the RF power source 132 may provide a RF power between about 1,000 Watts (W) to about 10,000 W in the processing region 120 to facilitate ionization of a precursor gas and generation of a plasma.

In some embodiments, which can be combined with other embodiments described herein, during deposition, the RF power source 132 provides a high frequency power (e.g., 13.5 MHz) between about 1,000 Watts and about 6,000 Watts. In some embodiments, which can be combined with other embodiments described herein, during deposition, the RF power source 132 provides a low frequency power (e.g., 350 kHz) between about 1 Watt and about 5,000 Watts. In some embodiments, without being bound by theory, it is believed when high RF power is delivered by the RF power source 132 for plasma generation, an increased plasma density may be produced and maintained despite processing occurring at a low pressure, such as less than about 1 Torr.

In some embodiments, to increase margins for an elevated RF processing regimes, for example for the delivery of up to about 6,000 Watts RF Power at about 13.5 MHz, the shaft 143 and/or the RF rod 130 may be configured with a larger RF connector to improve stability of RF delivery from the RF power source 132 and repeatability of the process. In some embodiments, the shaft 143 may be configured with a plurality of individual shunt capacitors to increase current carrying capacity for providing high RF current. In some embodiments, such configurations for the elevated RF processing regime provide for maintaining high plasma density even at low pressures, such as less than about 1 Torr, thereby preventing the need for additional inductively coupled plasma (ICP) or very high frequency (VHF) source components. In some embodiments, the foregoing configuration for providing a high power bottom RF feed to the substrate support 104 in turn provides a higher bias on the substrate side and a longer ion mean free path. Such configurations result in increases of carbon ion energy as well as the maintaining of high ion density and high power density. In some embodiments, critical components for RF delivery are further optimized with composite coating to prevent degradation or corrosion in response to high temperatures from the high RF power being delivered and improve reliability.

In some embodiments, the RF rod 130 may alternatively comprise dual RF rods (not shown) for coupling the bias electrode 129 to the RF power source 132. Use of the dual RF rods to transmit the RF current from the RF power source 132 can assist in preventing overheating from the delivery of the high RF current. Dual RF rods divide the RF current provided by the RF power source 132 to the bias electrode 129 into the two RF rods and thus prevents overheating by reducing the Joule heating (e.g., 12R heating) at each of the dual RF rods. Use of dual RF rods may also result in a more uniform temperature distribution across the substrate support 104, which in turn may translate into, for example, a more uniformly deposited amorphous carbon film across the substrate 154.

In some embodiments, the support member 104 is displaceable in the vertical direction. For example, a baffle 140 connected between the support member 104 and the chamber body 102 may extend and contract to allow for vertical movement of the support member 104. During operation, the substrate support 104 may raise to a higher position towards the faceplate 106 thereby decreasing a volume of the processing region 120 between the surface 142 of the substrate support 104 and the faceplate 106. Elevating the substrate support 104 to the higher position for processing the substrate 154 in a processing environment with a smaller volume may assist in providing enhanced plasma density uniformity in the processing region 120 during processing. In some embodiments, during a cleaning process, a cleaning gas is flowed into the process chamber 100 for cleaning the processing region 120. As such, confining the deposition process to a smaller volume in turn also allows for shorter clean times that can translate into increased throughput by the process chamber 100.

At least one controller 162 is coupled to the process chamber 100. The controller 162 includes a processor 164, a memory 166, and support circuits 168 that are coupled to one another. The processor 164 may be one of any form of general purpose microprocessor, or a general purpose central processing unit (CPU), each of which can be used in an industrial setting, such as a programmable logic controller (PLC), supervisory control and data acquisition (SCADA) systems, or other suitable industrial controller. The memory 166 is non-transitory and may be one or more of readily available memory such as random access memory (RAM), read only memory (ROM), or any other form of digital storage, local or remote. The memory 166 contains instructions, that when executed by the processor 164, facilitates execution of the method 300 (described below). The instructions in the memory 166 are in the form of a program product such as a program that implements the method of the present disclosure.

The program code of the program product may conform to any one of a number of different programming languages. Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are examples of the present disclosure.

In some embodiments, a source of plasma non-uniformity in process chamber 100 is the presence of a parasitic plasma. Parasitic plasmas can reduce plasma control and therefore limit process control in the process chamber. In PECVD process chambers, parasitic plasmas may be generated, at least in part, by an inefficient RF return path. For example, in a typical plasma chamber, the RF return path may pass along the chamber body 102 and back up to the substrate support 104 along a path that includes the baffle 140. This long path may result in arcing and energy dissipation into the surrounding vacuum space, and may cause a parasitic plasma to form around the substrate support of the plasma chamber.

In an embodiment, to maintain the uniformity and stability of the plasma energized by the high RF power applied and in a low pressure environment, the process chamber 100 may be configured with an RF return assembly for providing a simplified and shorter RF path that bypasses the baffle 140 of the process chamber 100.

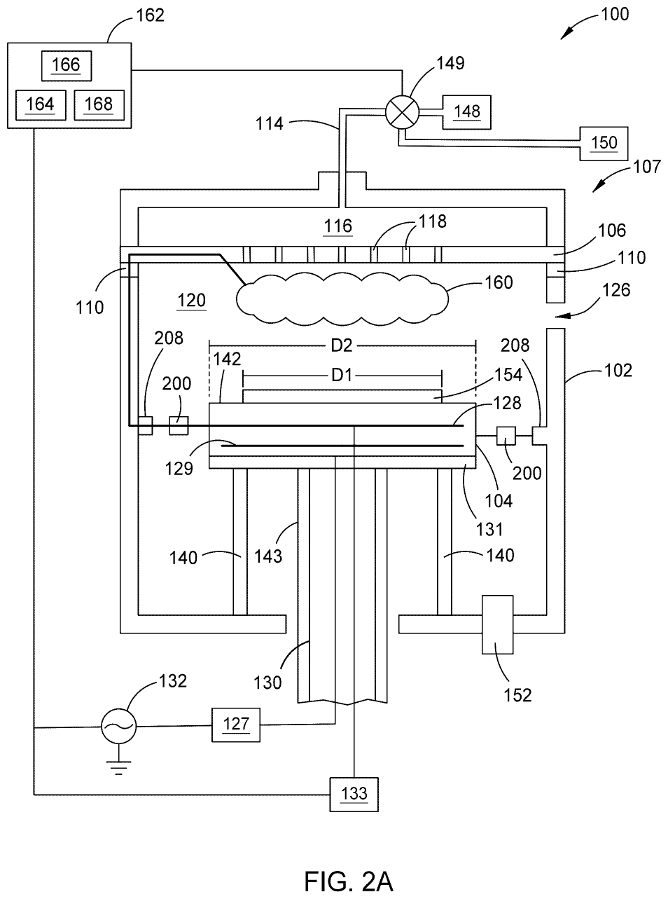

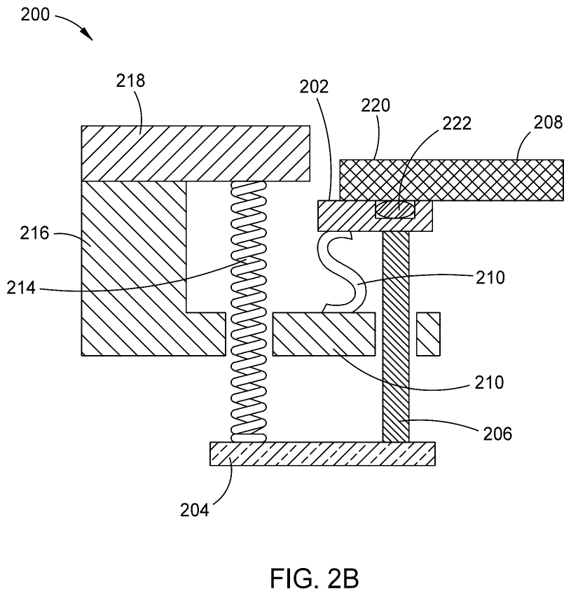

FIG. 2A is a schematic cross-sectional view of process chamber 100 that utilizes such an RF return assembly 200, according to certain embodiments of the present disclosure. The RF return assembly 200 may electrically couple the substrate support 104 and a RF return ledge 208 extending from the chamber body 102. During processing, a RF return path 212 may pass along the chamber body 102, into the RF return ledge 208, through the RF return assembly 200, and into the substrate support 104. The RF return path 212 bypasses the baffle 140 and is therefore shorter than passing along the chamber body 102 and up the baffle 140, as mentioned above.

FIG. 2B shows a cross-sectional view of an example RF return assembly 200 implemented with process chamber 100, in accordance with certain embodiments. In an embodiment, the RF return assembly 200 comprises a first ring 202 that is affixed to a second ring 204 by a pillar 206. The first ring 202 is brought into contact with the RF return ledge 208. In some embodiments, a groove 220 in the first ring 202 may be filled by an RF gasket 222. The RF gasket 222 is compressed against the RF return ledge 208 to provide improved electrical coupling between the first ring 202 and the RF return ledge 208. A flexible conductive band 210 electrically couples the first ring 202 to a first plate 216. In an embodiment, the first ring 202 is held against the RF return ledge 208 by a spring 214 that is attached between the second ring 204 and a second plate 218. In an embodiment, the first plate 216 and the second plate 218 may be portions of the substrate support 104. The spring 214 may be a tension spring. As such, as the substrate support 104 and the bias electrode 129 are displaced vertically, the spring 214 expands and supplies a force that pulls the first ring 202 and the second ring 204 up against the RF return ledge 208. This allows for the RF return path 212 to remain shorted around the baffle 140 in many different positions of the process chamber 100.

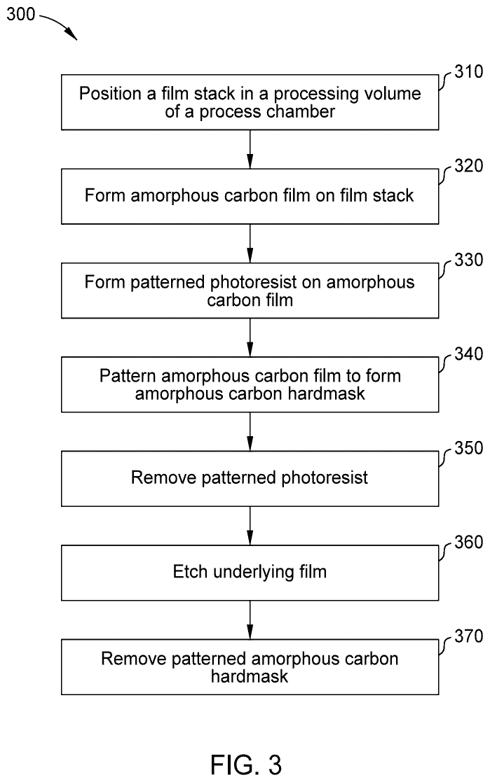

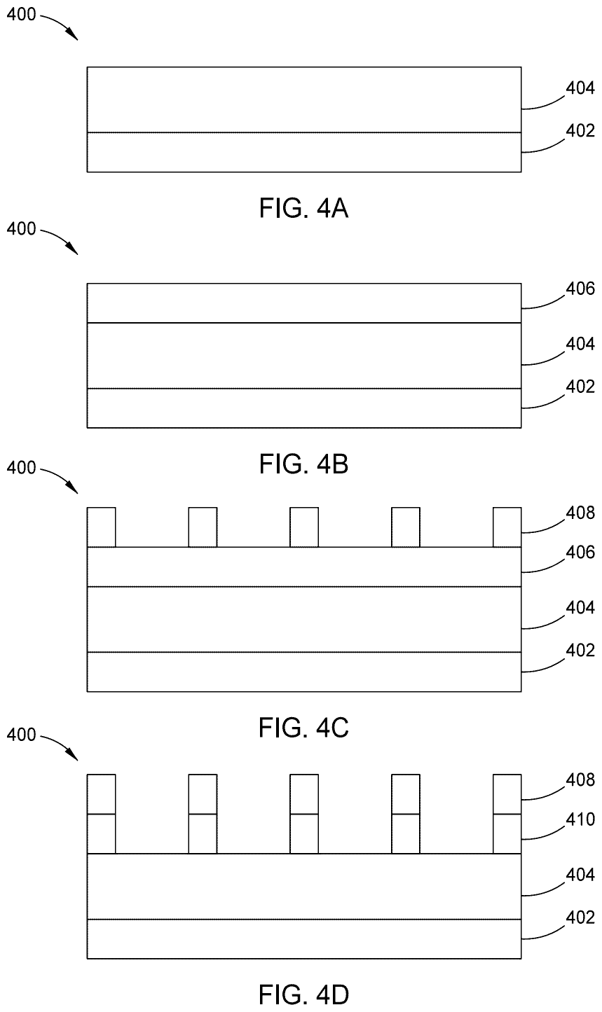

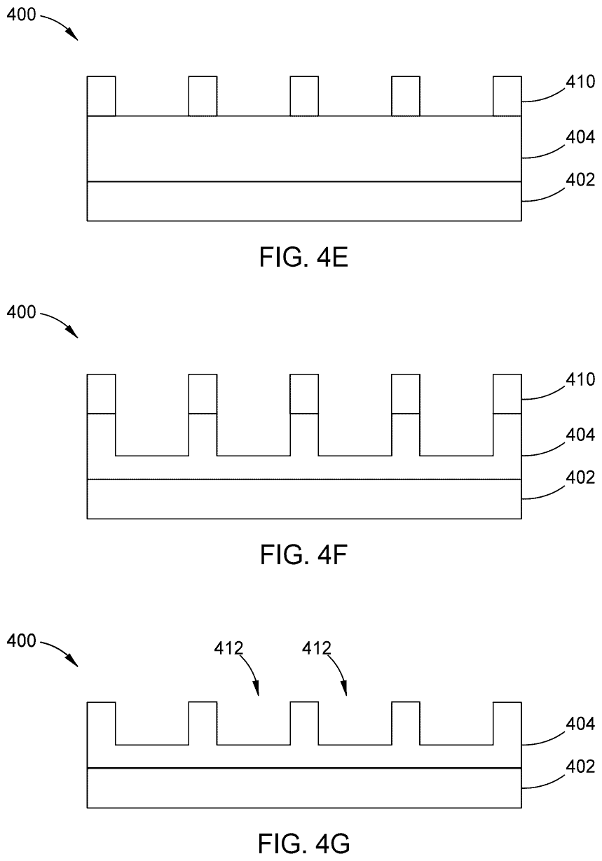

FIG. 3 depicts a process flow diagram of a method 300 for forming an amorphous carbon hardmask on a film stack disposed on a substrate, in accordance with one or more embodiments of the present disclosure. FIGS. 4A-4G depict a schematic cross-sectional view of a substrate structure illustrating a hardmask formation sequence according to method 300. Although the method 300 is described below with reference to a hardmask layer that may be formed on a film stack utilized to manufacture channel openings in the film stack for three dimensional semiconductor devices, the method 300 may also be used to advantage in other device manufacturing applications. Further, it should also be understood that the operations depicted in FIG. 3 may be performed simultaneously and/or in a different sequence than as depicted in FIG. 2.

The method 300 begins at operation 310 by positioning film stack 400 in a process chamber, such as the process chamber 100 depicted in FIG. 1. The film stack 400 comprises a substrate 402. The substrate 402 may be part of the film stack 400.

The substrate 402 may be the substrate 154 depicted in FIG. 1. In one embodiment, a surface of the substrate 154, as shown in FIG. 1, is substantially planar. Alternatively, the substrate 154 may have patterned structures, for example, a surface having trenches, holes, or vias formed therein. The substrate 154 may also have a substantially planar surface having a structure formed thereon or therein at a targeted elevation. While the substrate 154 is illustrated as a single body, it is understood that the substrate 154 may contain one or more materials used in forming semiconductor devices such as metal contacts, trench isolations, gates, bitlines, or any other interconnect features. The substrate 154 may comprise one or more metal layers, one or more dielectric materials, semiconductor material, and combinations thereof utilized to fabricate semiconductor devices. For example, the substrate 154 may include an oxide material, a nitride material, a polysilicon material, or the like, depending upon application. In one embodiment where a memory application is targeted, the substrate 154 may include the silicon substrate material, an oxide material, and a nitride material, with or without polysilicon sandwiched in between.

The substrate 154 may be any substrate or material surface upon which film processing is performed. For example, the substrate 154 may be a material such as crystalline silicon, silicon oxide, silicon oxynitride, silicon nitride, strained silicon, silicon germanium, tungsten, titanium nitride, doped or undoped polysilicon, doped or undoped silicon wafers and patterned or non-patterned wafers, silicon on insulator (SOI), carbon doped silicon oxides, silicon nitrides, doped silicon, germanium, gallium arsenide, glass, sapphire, low k dielectrics, and combinations thereof.

Turning to FIG. 4A, the film stack 400 includes the substrate 402 and a material layer 404 disposed thereon. The material layer 404, as utilized herein, includes any layer, which is disposed beneath an amorphous carbon film 406. For example, the amorphous carbon film 406 may be disposed directly on the material layer 404, such that the amorphous carbon film 406 and material layer 404 are in physical contact with each other. In one embodiment, the material layer 404 comprises a single layer. In another embodiment, the material layer 404 comprises a film stack.

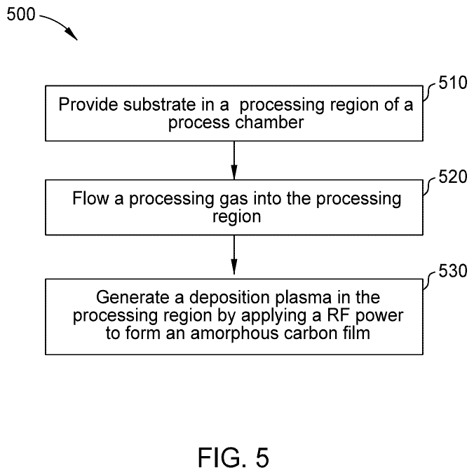

At operation 320, the amorphous carbon film 406 is formed on the material layer 404 disposed over the substrate 402, as illustrated in FIG. 4B. The amorphous carbon film 406 is deposited by a plasma enhanced chemical deposition process over the material layer 404. In some embodiments, the amorphous carbon film 406 is deposited according to the method 500 described in the process flow diagram of FIG. 5. The amorphous carbon film 406 may be deposited to a thickness, which corresponds to the subsequent etching requirements of the material layer 404. In one example, the amorphous carbon hardmask has a thickness of between about 300 Å and about 70 k Å, such as between about 500 Å and about 4000 Å, or between about 700 Å and about 1500 Å.

At operation 330, a photoresist layer 408, which is patterned, is formed over the amorphous carbon film 406 deposited on the material layer 404, as illustrated in FIG. 4C. Features or patterns may be transferred to the photoresist layer 408 from a photomask utilizing an energy source, such as light energy. In one embodiment, the photoresist layer 408 is a polymeric material and the patterning process is performed by a 193-nanometer immersion photolithography process, or other similar photolithography process. Similarly, lasers may also be utilized to perform the patterning process.

At operation 340, the amorphous carbon film 406 is patterned by, for example, a plasma etching process to form an amorphous carbon hardmask 410 as illustrated in FIG. 4D.

At operation 350, the photoresist layer 408 is removed as illustrated in FIG. 4E. The photoresist layer 408 may be removed by various advantageous photoresist removal processes.

At operation 360, the material layer 404 is dry etched, as illustrated in FIG. 4F, with plasma reactive gases. The material layer 404 etching may be performed in a plasma-process chamber, such as the chambers and systems described with regard to FIG. 1. In some embodiments, etchants, such as fluorocarbons, may preferentially remove the exposed portions of the material layer 404 as the amorphous carbon hardmask 410 is resistant to the active species of the etchants. Thus, the etchants are selective for the material layer 404 material.

At operation 370, the amorphous carbon hardmask 410 is removed. The amorphous carbon hardmask 410 may be removed by any advantageous hardmask removal process. In one example, oxygen plasma is utilized to remove the amorphous carbon hardmask 410. As shown in FIG. 4G, the resulting film stack 400 includes the material layer 404 having a plurality of feature 412, such as a high aspect ratio gap or trench, formed therein. The film stack 400 may then be subjected to further processing to form a functional semiconductor device.

FIG. 5 is a process flow diagram depicting one embodiment of a method 500 for forming an amorphous carbon film according to embodiments described herein. In one embodiment, the method 500 may be used to form the amorphous carbon film of operation 320. The method 500 begins at operation 510 by providing a substrate in a processing region of a process chamber. The process chamber may be the process chamber 100 depicted in FIG. 1. The substrate may be the substrate 154 or the substrate 402, depicted in FIG. 1 and FIGS. 4A-4G, respectively, or the material layer 404 depicted in FIGS. 4A-4G.

In some embodiments, the distance between the substrate support 104 and the gas distribution faceplate 106 (i.e., “spacing”) may be set to between about 200 mils to about 1,000 mils (e.g., between about 250 mils and about 600 mils; between about 300 mils to about 1,000 mils; or between about 400 mils and about 600 mils). In some embodiments, the chamber, the substrate, or both may be maintained at a temperature between about 200 degrees Celsius and about 900 degrees Celsius (e.g., between about 400 degrees Celsius and about 700 degrees Celsius; or between about 500 degrees Celsius to about 900 degrees Celsius).

At operation 520, a processing gas is flowed into the processing region 120. The processing gas may be flowed from the gas source 148 into the processing region 120 through the gas distribution faceplate 106. The processing gas may include at least one hydrocarbon precursor and/or carbon-containing precursor. The processing gas may further include an inert gas, a dilution gas, a nitrogen-containing gas, or combinations thereof. The hydrocarbon and/or carbon-containing precursor can be any liquid or gas, though the preferred precursor would be vapor at room temperature to simplify the hardware needed for material metering, control and delivery to the chamber.

In one embodiment, the hydrocarbon precursor of the processing gas is a gaseous hydrocarbon, such as a linear hydrocarbon. In one embodiment, the hydrocarbon precursor is a compound having a general formula CₓH_{y}, where x has a range of between 1 and 20 and y has a range of between 1 and 20. In one embodiment, the hydrocarbon compound is an alkane. Suitable hydrocarbon precursor compounds include, for example, methane (CH₄), acetylene (C₂H₂), ethylene (C₂H₄), ethane (C₂H₆), propylene (C₃H₆), and butylenes (C₄H₈), cyclobutane (C₄H₈), methylcyclopropane (C₄H₈), benzene (C₆H₆), cyclohexane (C₆H₁₂), pentane (C₅H₁₂), and propane (C₃H₈). Suitable butylenes include 1-Butene, 2-Butene, and isobutylene.

In some embodiments, hydrocarbon precursors with lower ionization and/or lower mass may be used to increase deposition rate of the amorphous carbon film. In one example, C₂H₂ may be preferable due to its lower ionization potential and thus higher ion density, as compared to another otherwise suitable hydrocarbon precursor, such as C₃H₆, with higher ionization potential and mass. In general, higher ion energy during deposition can cause a decrease in deposition rate due to the excessive ion etching effect with high energy species. For example, with the same high RF power being delivered, use of C₂H₂ as the hydrocarbon precursor increases the deposition rate by about 2×, as compared to the usage of C₃H₆ as the hydrocarbon precursor for forming the amorphous carbon film.

Suitable dilution gases such as helium (He), argon (Ar), hydrogen (H₂), nitrogen (N₂), Krypton (Kr), or combinations thereof, among others, may be added to the processing gas. Ar, He, and N₂ are used to control the density and deposition rate of the amorphous carbon hardmask. In some cases, the addition of N₂ can be used to control the hydrogen ratio of the amorphous carbon hardmask, as discussed below.

In some embodiments, a flow rate of the hydrocarbon precursor may be from about 1 sccm to about 2,000 sccm (e.g., between about 100 sccm and about 2,000 sccm; or between about 400 sccm and about 1000 sccm). In some embodiments, a flow rate ratio of a dilution gas flow rate to the precursor gas flow rate may be in a range between a 1:1 ratio and a 20:1 ratio. Alternatively, dilution gases may not be used during the deposition.

A nitrogen-containing gas may be supplied with the processing gas into the process chamber 100. Suitable nitrogen-containing compounds include, for example, pyridine, aliphatic amine, amines, nitriles, ammonia and similar compounds.

An inert gas, such as argon (Ar) and/or helium (He) may be supplied with the processing gas into the plasma-process chamber 100. Other inert gases, such as nitrogen (N₂) and nitric oxide (NO), may also be used to control the density and deposition rate of the amorphous carbon layer. Additionally, a variety of other processing gases may be added to the processing gas to modify properties of the amorphous carbon film. In one embodiment, the processing gases may be reactive gases, such as hydrogen (H₂), ammonia (NH₃), a mixture of hydrogen (H₂) and nitrogen (N₂), or combinations thereof. The addition of H₂ and/or NH₃ may assist in controlling the hydrogen content of the deposited amorphous carbon hardmask.

In some embodiments, the precursors of the processing gas supplied to the processing region may generate and maintain a processing pressure in the substrate processing chamber of less than or about 100 mTorr. Additional exemplary processing pressure ranges include less than or about 1 Torr, less than or about 500 mTorr, less than or about 3 Torr, less than or about 2 Torr, less than or about 800 mTorr, less than or about 200 mTorr, less than or about 0.5 Torr, or less, among other pressure ranges. By lowering the processing pressure in some embodiments, increased ion bombardment may occur by increasing the mean-free path between atoms. This may increase the distance of travel between collisions, which may increase ion energy and bombardment with the surface of the as deposited amorphous carbon film. This may further facilitate reduction of hydrogen content and increased formation of improved carbon bonding within the carbon film formed to increase the density of the deposited film.

At operation 530, a deposition plasma is generated by delivering a plasma power to the processing region 120 to form an amorphous carbon film, such as amorphous carbon film 406, on the substrate. In some embodiments, the plasma power may be delivered as a bias power that originates with a RF power source in electrical contact with a substrate support that is in electrical contact with the substrate. As noted previously, some embodiments of the present disclosure may deliver a higher RF bias power to produce a bias plasma with a higher plasma power. It is believe higher plasma power during plasma deposition may assist to improve the film characteristics and structure of the as-deposited material.

In some embodiments, the bias plasma may be produced at a delivered RF power of greater than or about 1000 W, greater than or about 2000 W, greater than or about 3000 W, greater than or about 4000 W, greater than or about 5000 W, greater than or about 6000 W, or greater. By increasing the plasma power, the bombardment energy of carbon ions during film deposition increases. Bombardment from such high energy carbon ions in turn may modify the film structure of the deposited materials to improve carbon bonding and reduce hydrogen incorporation. For example, when the bombardment energy of carbon ions exceeds the critical energy required for sub-plantation, for example, carbon ions with ion bombardment energy of around 30 eV can penetrate the subsurface of the as deposited amorphous carbon film. At that time, the penetrating carbon ions may induce the displacement of hydrogen and break the carbon-hydrogen chemical bonds since the energy threshold for the displacement of hydrogen is only 2.5 eV. In some embodiments, the RF power source may produce power at a RF frequency of, for example, about 350 kHz to about 162 MHz (e.g., 350 kHz, 2 MHz, 13.56 MHz, 27 MHz, 40 MHz, 60 MHz, 100 MHz, or 162 MHz).

The deposition plasma may be a bias plasma generated and as described above. The deposition plasma may be formed and may be energized by coupling a RF power into the processing gas. The RF power may be a dual-frequency RF power that has a high frequency component and a low frequency component. The RF power may be applied at a power level between about 1000 W and about 7000 W (e.g., between about 3000 W and about 6000 W), which may be all high-frequency RF power, for example at a frequency of about 13.56 MHz, or may be a mixture of high-frequency power and low frequency power, for example at a frequency of about 350 kHz. For most applications, the RF plasma is maintained for a time period to deposit an amorphous carbon film having a thickness between about 500 Å and about 70,000 Å. The flow of processing gas continuing until a targeted thickness of the amorphous carbon film is reached.

Any excess processing gases and by-products from the deposition of the season layer may then be removed from the processing region by performing an optional purge/evacuation process.

The following non-limiting examples are provided to further illustrate embodiments described herein. However, the examples are not intended to be all inclusive and are not intended to limit the scope of the embodiments described herein.

In certain embodiments, high-density amorphous carbon films were fabricated according to the methods of the present disclosure. The resulting amorphous carbon film carbon films had densities closer to the theoretical density of sp² graphite (2.26 g/cc) than conventional amorphous carbon films, as well as lower percentages of hydrogen content.

Table 1 shows an etch selectivity comparison and accompanying film properties between a conventional amorphous carbon hardmask (Reference) and various embodiments of amorphous carbon hardmasks (Masks A-C) formed according to the methods of the present disclosure.

TABLE 1

| Films | Reference | Mask A | Mask B | Mask C |
|---|---|---|---|---|
| Precursor | C₃H₆ | C₃H₆ | C₃H₆ | C₂H₂ |
| RI (633 nm) @ 3.5 kA | 2.09 | 2.11 | 2.14 | 2.18 |
| K (633 nm) @ 3.5 kA | .69 | .72 | .8 | |
| H % | 11% | 20% | 8.8% | 7.9% |
| Density (g/cc) | 1.82 | 1.86 | 1.92 | 2.12 |
| Blanket etch selectivity | 1X | 1.2X | 1.3X | >1.3X |
| improvement | | | | |
| Modulus (GPa) | 68 | 78 | 102 | 118 |
| Hardness (GPa) | 8.5 | 9.8 | 13.5 | 14.9 |

The amorphous carbon film formed by method 500 may serve as a hardmask layer during an etching process due to their high etching selectivity. Suitable processes include gate manufacturing applications, contact structure applications, shallow trench isolation (STI) process, and the like. In some embodiments, where the amorphous carbon film is used as an etch stop layer or used as different films for different process purposes, the mechanical or optical properties of the amorphous carbon film may be adjusted as well to meet the particular process need.

Thus, methods for forming a highly etch selective amorphous carbon film having high density and low hydrogen content are provided by a plasma deposition process according to embodiments described herein. The present disclosure advantageously provide an amorphous carbon film with targeted mechanical properties, such as increased film density and reduction in hydrogen incorporation, resulting in improvements in etching selectivity. Some embodiments of the present disclosure provide a unique process that increases the density of the film by about 15% by delivering high RF bias power to increase ion bombardment energy of carbon ions. In some embodiments, the present disclosure provides a unique process that reduces hydrogen incorporation in the amorphous carbon film by increasing substrate temperature during processing. In some embodiments, further improvement of etch selectivity is achieved through reduction in hydrogen content or hydrogen incorporation in the film, which decreases film stress in the amorphous carbon film. The resulting amorphous carbon hardmask provided by the present disclosure has shown an improvement in etch selectivity of at least about 30% as compared to conventional pure carbon hardmask films.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A method of forming an amorphous carbon film, comprising:
flowing a processing gas into a processing region of a process chamber having a substrate with a material layer disposed thereon positioned on a substrate support;
generating a deposition plasma from the processing gas by applying a RF power to the processing region to form the amorphous carbon film on the material layer, wherein the RF power is in a range between about 1000 W and about 7000 W, and the substrate is maintained at a temperature between about 200 degrees Celsius and about 900 degrees Celsius;
patterning the amorphous carbon film in a pattern; and
etching the pattern into the material layer.

2. The method of claim 1, wherein the RF power is maintained in a range between about 1000 W and about 7000 W to provide the deposition plasma with high ion energy when forming the amorphous carbon film.

3. The method of claim 1, wherein the RF power is delivered to the processing region from a RF power source electrically connected to the substrate support, and the RF power is delivered at a frequency from about 350 kHz to about 162 MHz.

4. The method of claim 1, wherein the RF power is delivered to the processing region from a dual-frequency RF power source, the dual-frequency RF power source providing a low frequency RF power of about 350 kHz in combination with a high frequency power of about 13.56 MHz.

5. The method of claim 1, wherein the processing gas comprises a hydrocarbon precursor flowed at a hydrocarbon precursor flow rate, the hydrocarbon precursor comprising methane (CH₄), acetylene (C₂H₂), ethylene (C₂H₄), ethane (C₂H₆), propylene (C₃H₆), and butylenes (C₄H₈), cyclobutane (C₄H₈), methylcyclopropane (C₄H₈), benzene (C₆H₆), cyclohexane (C₆H₁₂), pentane (C₅H₁₂), or propane (C₃H₈).

6. The method of claim 5, wherein the processing gas further comprises a dilution gas comprising helium (He), argon (Ar), hydrogen (H₂), nitrogen (N₂), Krypton (Kr), or combinations thereof.

7. The method of claim 5, wherein the hydrocarbon precursor flow rate is in a range from about 1 sccm to about 2,000 sccm.

8. The method of claim 6, wherein the dilution gas is flowed at a dilution gas flow rate, and a flow rate ratio of the dilution gas flow rate to the hydrocarbon precursor flow rate is in a range between a 1:1 ratio and a 20:1 ratio.

9. The method of claim 1, wherein a pressure within the processing region is between about 100 mTorr and about 5 Torr.

10. The method of claim 1, wherein the processing region is at least partially defined by a faceplate of the process chamber and the substrate support, and a distance between a bottom surface of the face and the substrate support when forming the amorphous carbon film is between about 250 mils and about 1,000 mils.

11. The method of claim 1, wherein the deposition plasma comprises carbon ions energized by the RF power, the carbon ions comprising ion bombardment energy equal to or greater than about 30 eV.

12. A method of forming an amorphous carbon film, comprising:
providing a substrate having a material layer disposed thereon on a substrate support in a processing region of a process chamber;
flowing a processing gas into the processing region; and
generating a deposition plasma of the processing gas by applying a RF power to the processing region to form the amorphous carbon film on the material layer, wherein the RF power is between about 1000 W and about 7000 W, and the amorphous carbon film has a density greater than about 1.9 g/cc.

13. The method of claim 12, wherein the amorphous carbon film comprises a thickness between about 500 Å and about 70,000 Å.

14. The method of claim 12, wherein the amorphous carbon film comprises a hydrogen content of less than about 10%.

15. The method of claim 12, wherein the amorphous carbon film comprises a surface roughness (Ra) of less than 1 nm.

16. The method of claim 12, wherein the amorphous carbon film comprises a stress (MPa) at 500 nm of from about −1100 MPa to about 0.

17. The method of claim 12, wherein the amorphous carbon film comprises a refractive index at 350 nm of from about 2.11 to about 2.18.

18. The method of claim 12, wherein the amorphous carbon film comprises a Young's modulus (GPa) of from about 70 GPa to about 120 GPa.

19. An amorphous carbon film for use in processing a substrate, the amorphous carbon film comprising a density greater than about 1.9 g/cc and a hydrogen content of less than about 10%, and wherein the amorphous carbon film is formed by a plasma deposition process using a RF power between about 1000 W and about 7000 W, and serves as a hardmask on the substrate in an etch process.

20. The amorphous carbon film of claim 19, comprising a thickness between about 500 Å and about 70,000 Å.
